(19) United States
(12) Patent Application Publication
(10) Pub. No.: US 2025/0040137 A1
(43) Pub. Date: Jan. 30, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventors: Ji Hyeun SHIN, Icheon-si Gyeonggi-do (KR); Da Yung BYUN, Icheon-si Gyeonggi-do (KR)

(73) Assignee: SK hynix Inc., Icheon-si Gyeonggi-do (KR)

(21) Appl. No.: 18/412,827

(22) Filed: Jan. 15, 2024

(30) Foreign Application Priority Data
Jul. 27, 2023 (KR) 10-2023-0098156

(51) Int. Cl. H10B 43/27; H01L 23/60

(52) U.S. Cl. CPC H10B 43/27; H01L 23/60

(57) ABSTRACT

A memory device and a manufacturing method of the memory device are provided. The memory device includes a discharge contact; a source line adjacent to and spaced apart from the discharge contact; an etch stop pattern located between the discharge contact and the source line, the etch stop pattern being closer to the source line than the discharge contact; and a sub-support pattern located on the source line and the etch stop pattern.

### CROSS-REFERENCE TO RELATED APPLICATION

The present application claims priority under 35 U.S.C. § 119(a) to Korean patent application number 10-2023-0098156 filed on Jul. 27, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a discharge contact located in a connection region and a manufacturing method of the memory device.

### 2. Related Art

A memory device may include a memory cell array in which data is stored, a peripheral circuit configured to perform a program, read or erase operation of the memory cell array, and a control circuit configured to control the peripheral circuit.

The memory cell array may include a plurality of memory blocks. When the memory blocks are formed in a three-dimensional structure, the memory blocks may be separated from each other by slit regions.

The memory blocks formed in the three-dimensional structure may include a stack structure in which memory cells are stacked in a vertical direction from a substrate. The stack structure may include a plurality of gate lines and a plurality of insulating layers, which are alternately stacked. The memory blocks may be located in a cell region of the memory device.

Connection regions may be specified at both ends of the cell region.

A discharge contact for removing dummy ions that may be generated in a manufacturing process of the memory device may be located in the connection region. A source line may be located at the periphery of the discharge contact, and the source line and the discharge contact may be spaced apart from each other. Support patterns may be located on the top of the source line. The support patterns may correspond to a structure supporting the stack structure constituting the memory blocks.

The discharge contact may be formed of a conductive material to discharge dummy ions. Therefore, the discharge contact should be spaced apart from the source line. When a distance between the source line and the discharge contact is excessively shorter than a reference distance, a bridge may occur between the source line and the discharge contact in the manufacturing process of the memory device. When the distance between the source line and the discharge contact is excessively longer than the reference distance, the size of the memory device may increase.

### SUMMARY

In accordance with an aspect of the present disclosure, there is provided a memory device including: a discharge contact; a source line adjacent to and spaced apart from the discharge contact; an etch stop pattern located between the discharge contact and the source line, the etch stop pattern being closer to the source line than the discharge contact; and a sub-support pattern located on the source line and the etch stop pattern.

In accordance with another aspect of the present disclosure, there is provided a memory device including: a first portion and a second portion of a source line, extending in a first direction, the first portion and the second portion being arranged to be parallel to each other; a discharge contact located between the first portion and the second portion of the source line; a first etch stop pattern located between the discharge contact and the first portion of the source line; a second etch stop pattern located between the discharge contact and the second portion of the source line; a first sub-support pattern located on a region in which the first portion of the source line is adjacent to and spaced apart from the first etch stop pattern face each other; and a second sub-support pattern located on a region in which the second portion of the source line is adjacent to and spaced apart from the second etch stop pattern face each other.

In accordance with still another aspect of the present disclosure, there is provided a method of manufacturing a memory device, the method including: forming a first portion and a second portion, which correspond to a source line, on a peripheral structure, and forming an open region insulating layer between the first and second portions; forming, in the open region insulating layer, a first etch stop pattern adjacent to the first portion and a second etch stop pattern adjacent to the second portion; forming a discharge contact penetrating the open region insulating layer between the first and second etch stop patterns; forming a pre-stack structure on the first and second portions, the first and second etch stop patterns, the open region insulating layer, and the discharge contact; performing an etching process for forming a first trench exposing a portion of the first etch stop pattern and a portion of the first portion while penetrating the pre-stack structure and a second trench exposing a portion of the second etch stop pattern and a portion of the second portion while penetrating the pre-stack structure; and forming a first sub-support pattern in the first trench and forming a second sub-support pattern in the second trench.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device.

FIG. 2 is a diagram illustrating a memory cell array.

FIG. 3 is a plan view illustrating a memory device in accordance with an embodiment of the present disclosure.

FIG. 4 is a sectional view illustrating a memory device in accordance with an embodiment of the present disclosure.

FIG. 5 is a perspective view illustrating a memory device in accordance with an embodiment of the present disclosure.

FIGS. 6A to 6S are views illustrating a manufacturing method of a memory device in accordance with an embodiment of the present disclosure.

FIG. 7 is a diagram illustrating a memory card system to which the memory device of the present disclosure is applied.

FIG. 8 is a diagram illustrating a Solid State Drive (SSD) system to which the memory device of the present disclosure is applied.

### DETAILED DESCRIPTION

The specific structural and functional descriptions disclosed herein are merely illustrative for the purpose of describing embodiments according to the concept of the present disclosure. Additional embodiments according to the concept of the present disclosure can be implemented in various forms. Thus, the present disclosure should not be construed as limited to the embodiments set forth herein.

Hereinafter, it will be understood that, although the terms “first,” “second,” etc. may be used herein to describe various elements, these elements should not be limited by these terms. These terms are only used to distinguish one element from another element.

Embodiments provide a memory device and a manufacturing method of the memory device, which can secure a margin between the source line and the discharge contact.

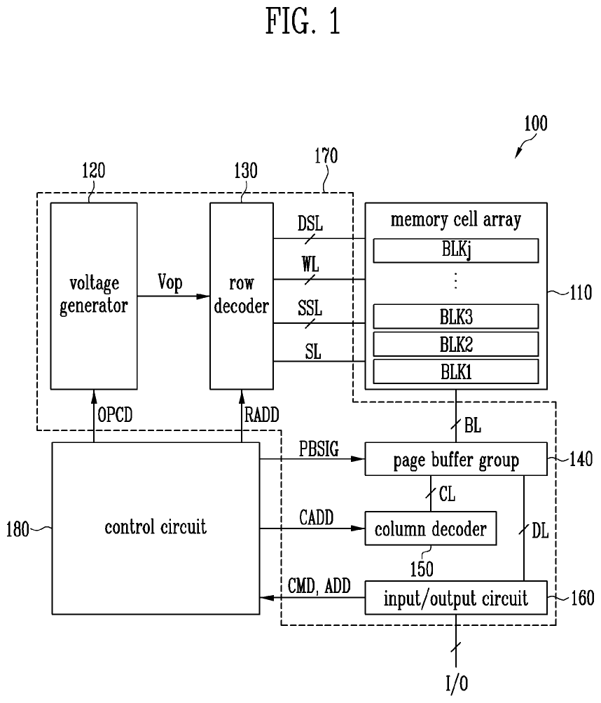

FIG. 1 is a diagram illustrating a memory device.

Referring to FIG. 1, the memory device 100 may include a memory cell array 110, a peripheral circuit 170, and a control circuit 180.

The memory cell array 110 may include first to jth memory blocks BLK1 to BLKj. Each of the first to jth memory blocks BLK1 to BLKj may include memory cells capable of storing data. Drain select lines DSL, word lines WL, source select lines SSL, and a source line may be connected to each of the first to jth memory blocks BLK1 to BLKj, and bit lines BL may be commonly connected to the first to jth memory blocks BLK1 to BLKj.

The first to jth memory blocks BLK1 to BLKj may be formed in a two-dimensional structure or a three-dimensional structure. Memory blocks having a two-dimensional structure may include memory cells arranged in parallel to a substrate. Memory blocks having a three-dimensional structure may include memory cells stacked in a vertical direction from a substrate. In this embodiment, memory blocks formed in a three-dimensional structure are disclosed.

The memory cells may store one-bit or two-or-more-bit data according to a program manner. For example, a manner in which one-bit data is stored in one memory cell is referred to as a single level cell (SLC) manner, and a manner in which two-bit data is stored in one memory cells is referred to as a multi-level cell (MLC) manner. A manner in which three-bit data is stored in one memory cell is referred to as a triple level cell (TLC) manner, and a manner in which four-bit data is stored in one memory cell is referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 is configured to generate program voltages, turn-on voltages, turn-off voltages, negative voltages, precharge voltages, verify voltages, read voltages, pass voltages, and erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation and may be used to increase a threshold voltage of memory cells connected to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or the source select transistors. For example, the turn-off voltage may be set to 0V. The precharge voltages may be voltages higher than 0V and may be applied to the bit lines in a read operation. The verify voltages may be used in a verify operation for determining whether a threshold voltage of selected memory cells has been increased to a target level. The verify voltages may be set to various levels according to the target level and may be applied to a selected word line.

The read voltages may be applied to a selected word line in a read operation of selected memory cells. For example, the read voltages may be set to various levels according to a program manner of the selected memory cells. The pass voltages may be voltages applied to unselected word lines, among the word lines WL, in a program or read operation and may be used to turn on memory cells connected to the unselected word lines.

The erase voltages may be used in an erase operation for erasing memory cells included in a selected memory block and may be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines and may be connected to the first to jth memory blocks BLK1 to BLKj through the drain select lines DSL, the word lines WL, the source select lines SSL, and the source line SL.

The page buffer group 140 may include page buffers (not shown) connected to each of the first to jth memory blocks BLK1 to BLKj. The page buffers (not shown) may be connected to the first to jth memory blocks BLK1 to BLKj, respectively, through the bit lines BL. In a read operation, in response to page buffer control signals PBSIG, the page buffers (not shown) may sense a current or a voltage of the bit lines BL, which varies according to threshold voltages of selected memory cells, and may temporarily store sensed data.

The column decoder 150 may be configured to transmit data between the page buffer group 140 and the input/output circuit 160 in response to a column address CADD. For example, the column decoder 150 may be connected to the page buffer group 140 through column lines CL and may transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and may transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation on a memory block selected by the address ADD. When the command CMD input to the control circuit 180 is a command corresponding to a read operation, the control circuit 180 may control the peripheral circuit 170 to perform the read operation on the selected memory block and output read data. When the command CMD input to the control circuit 180 is a command corresponding to an erase operation, the control circuit 180 may control the peripheral circuit 170 to perform the erase operation on the selected memory block.

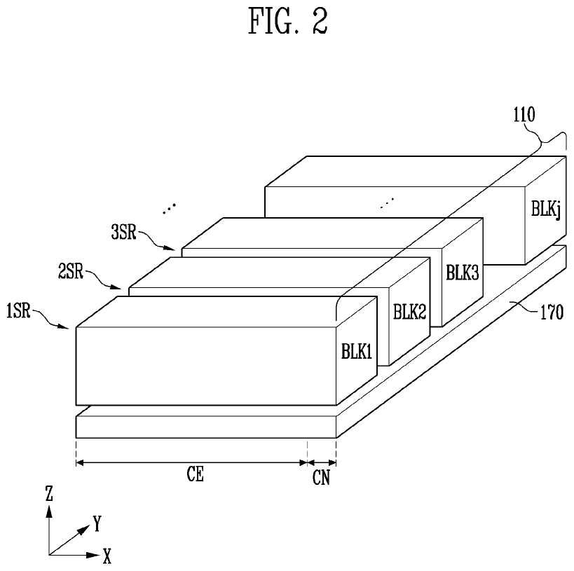

FIG. 2 is a diagram illustrating a memory cell array.

Referring to FIG. 2, the memory cell array 110 may be located on the peripheral circuit 170. For example, the peripheral circuit 170 may be located on one substrate, and the memory cell array 110 may be located on the peripheral circuit 170. Alternatively, the peripheral circuit 170 and the memory cell array 110 may be formed on different substrates, and the peripheral circuit 170 and the memory cell array 110 may be in contact with each other.

The memory cell array 110 may include first to jth memory blocks BLK1 to BLKj. The first to jth memory blocks BLK1 to BLKj may be disposed to be spaced apart from each other along a Y direction. The first to jth memory blocks BLK1 to BLKj may be configured identically to one another and may be separated from each other by slit regions 1SR, 2SR, 3SR, . . . . Each of the slit regions 1SR, 2SR, 3SR, . . . may extend along an X direction. For example, the first memory block BLK1 may be located between a first slit region 1SR and a second slit region 2SR, and the second memory block BLK2 may be located between the second slit region 2SR and a third slit region 3SR. The first and second memory blocks BLK1 and BLK2 may be separated from each other by the second slit region 2SR.

Each of the first to jth memory blocks BLK1 to BLKj may include a cell region CE and a connection region CN. Memory cells configured to store data may be located in the cell region CE, and a plurality of connection structures connected to the peripheral circuit 170 may be located in the connection region CN. For example, the connection structures may include contacts, lines, support patterns, and discharge contacts. The contacts may be configured to be in contact with gate lines extending from the cell region CE or to be in contact with the peripheral circuit 170 located on the bottom of the memory cell array 110. The lines may be configured to be electrically connected to the contacts. The support patterns may be configured to support a stack structure located in the connection region CN. The discharge contacts may be configured to discharge, to a ground terminal, dummy ions that may be generated in a manufacturing process of the memory device. For example, the dummy ions may be mainly generated in an etching process. When the dummy ions remain in a partial region of the memory device, the reliability of operation may be deteriorated by the dummy ions in a program, read, or erase operation of the memory device. Therefore, the discharge contacts may discharge the dummy ions that may be generated in the manufacturing process of the memory device through the ground terminal.

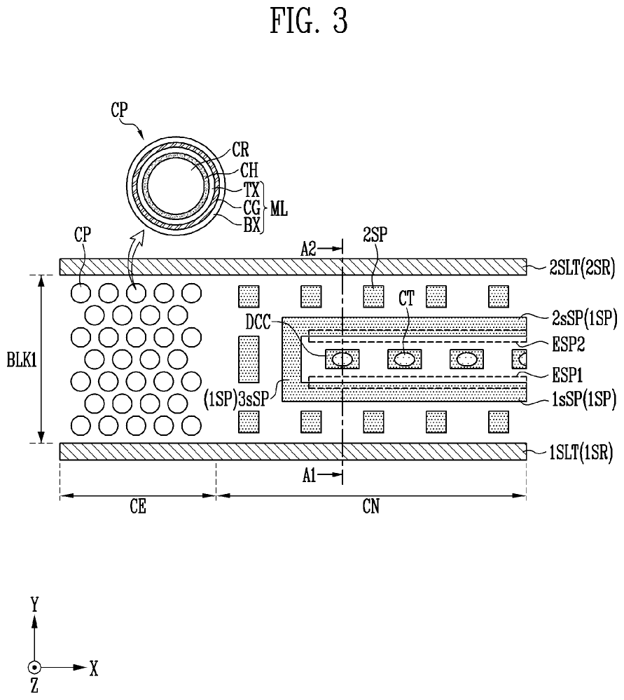

FIG. 3 is a plan view illustrating a memory device in accordance with an embodiment of the present disclosure.

Referring to FIG. 3, a layout of the first memory block BLK1, among the first to jth memory blocks BLK1 to BLKj, shown in FIG. 2, is illustrated.

The first memory block BLK1 may be located between first and second slit structures 1SLT and 2SLT. The first and second slit structures 1SLT and 2SLT may be structures formed in first and second slit regions 1SR and 2SR and may be formed of an insulating material or a conductive material or may be formed of the insulating material and the conductive material.

The first memory block BLK1 may be divided into a cell region CE and a connection region CN.

Cell plugs CP including memory cells may be included in the cell region CE. Each of the cell plugs CP may include a core pillar CR, a channel layer CH, and a memory layer ML, which constitute a memory cell or select transistors. The memory layer ML may include a tunnel insulating layer TX, a charge trap layer CG, and a blocking layer BX. The core pillar CR may have a circular pillar shape and may be formed of an insulating material or a conductive material. The channel layer CH may have a cylindrical shape surrounding a side surface of the core pillar CR and may be formed of poly-silicon. The tunnel insulating layer TX may have a cylindrical shape surrounding a side surface of the channel layer CH and may be formed of an oxide layer. The charge trap layer CG may have a cylindrical shape surrounding a side surface of the tunnel insulating layer TX and may be formed of a nitride layer. The blocking layer BX may have a cylindrical shape surrounding a side surface of the charge trap layer CG and may be formed of an oxide layer. When assuming that the first and second slit structures 1SLT and 2SLT extend along the X direction and are spaced apart from each other along the Y direction, the cell plugs CP, extending in a Z direction, may be arranged to be spaced apart from each other along the X and Y directions.

First and second support patterns 1SP and 2SP, contacts CT, discharge contacts DCC, and first and second etch stop patterns ESP1 and ESP2 may be included in the connection region CN. The first and second support patterns 1SP and 2SP may be configured to support a stack structure constituting the memory block and may be formed of an insulating material. For example, the first and second support patterns 1SP and 2SP may be formed of an oxide layer. For example, the first and second support patterns 1SP and 2SP may be formed of a silicon oxide layer.

The description of the components will be made from a plan-view perspective as shown in FIG. 3. The first support pattern 1SP may be configured in the form of lines connected to each other. For example, the first support pattern 1SP may include first and second sub-support patterns 1sSP and 2sSP, which extend in the X direction, and may be arranged in parallel to each other. Additionally, a third sub-support pattern 3sSP may connect an end of the first sub-support pattern 1sSP to an end of the and second sub-support pattern 2sSP. The second support patterns 2SP may be configured in the form of islands spaced apart from each other and may be spaced apart from the first and second slit structures 1SLT and 2SLT and the first support pattern 1SP. For example, the second support patterns 2SP may be disposed between the first slit structure 1SLT and the first sub-support pattern 1sSP, between the cell plugs CP and the third sub-support pattern 3sSP, and between the second slit structure 2SLT and the second sub-support pattern 2sSP. In other words, the second support patterns 2SP may be formed around the first support pattern 1SP within the boundaries created by the first slit structure 1SLT, the second slit structure 2SLT, and the cell plugs CP. The second support patterns 2SP may be formed in a quadrangular or circular shape or may be formed in a curved shape.

The contacts CT and the discharge contacts DCC may be located in a region surrounded by the first support pattern 1SP. The contacts CT may be configured to electrically connect structures spaced apart from each other in the Z direction. Therefore, the contacts CT may be formed of a conductive layer. Although not shown in the drawing, the contacts CT may be located between the second support patterns 2SP in addition to the region surrounded by the first support pattern 1SP.

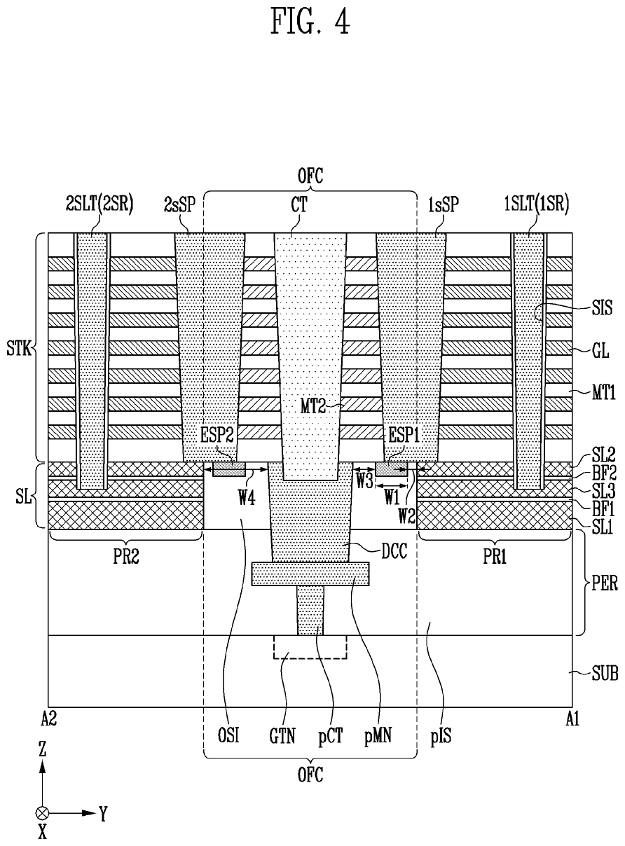

The discharge contacts DCC may be disposed below (below in the Z direction as shown in FIG. 4) the contacts CT. The discharge contacts DCC may be configured to discharge dummy ions that may be generated in a manufacturing process of the memory device through a ground terminal. The dummy ions may be mainly generated in a dry etching process. For example, the dry etching process may be mainly performed using a Reactive Ion Etching (RIE) method or a method obtained by applying the RIE method. Plasma may be used in the etching process using the RIE method or the method obtained by applying the RIE method. Positive ions generated by the plasma may collide with an etching target layer, and therefore, the binding force of a surface of the etching target layer may become weak. Molecules at a portion at which the binding force becomes weak in the etching target layer may be discharged, together with radicals, from a chamber. Some positive ions may remain in the etching target layer. The remaining positive ions may become dummy ions and may have influence on a region in which the dummy ions remain. Therefore, the discharge contacts DCC may be located in the region in which the dummy ions remain and may be electrically connected to ground terminals. The dummy ions may be discharged through the discharge contacts DCC and the ground terminals to be removed from the memory device.

In a plan view, the first and second etch stop patterns ESP1 and ESP2 may be located between the discharge contacts DCC and respective portions of the first support pattern 1SP. The first and second etch stop patterns ESP1 and ESP2 may be formed of a conductive layer. For example, the first and second etch stop patterns ESP1 and ESP2 may be formed of the same material as a second source layer SL2 (see FIG. 4). For example, the first and second etch stop patterns ESP1 and ESP2 may be formed of a conductive material, such as poly-silicon, tungsten, or nickel. The first and second etch stop patterns ESP1 and ESP2 may be spaced apart from the discharge contacts DCC and may overlap with the first support pattern 1SP. For example, the first and second etch stop patterns ESP1 and ESP2 may extend in the X direction and may be arranged to be parallel to each other. The first etch stop pattern ESP1 may be located between the discharge contacts DCC and the first sub-support pattern 1sSP, and a portion of the first etch stop pattern ESP1 may overlap with the first sub-support pattern 1sSP. The second etch stop pattern ESP2 may be located between the discharge contacts DCC and the second sub-support pattern 2sSP, and a portion of the second etch stop pattern ESP2 may overlap with the second sub-support pattern 2sSP.

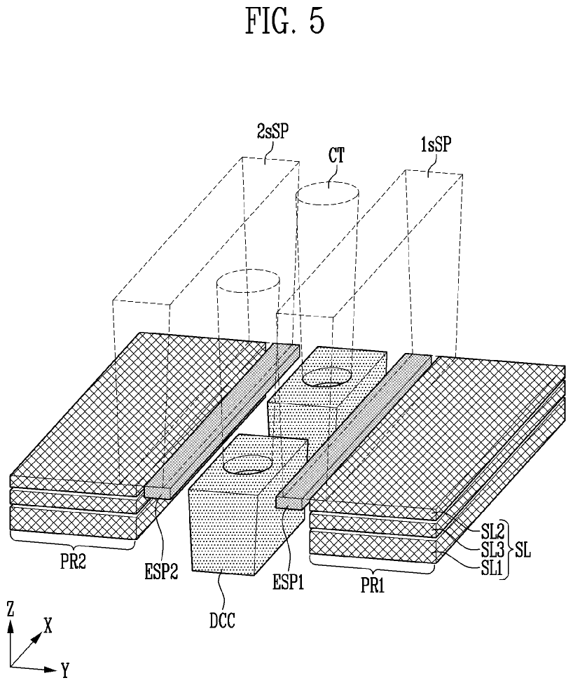

FIG. 4 is a sectional view illustrating a memory device in accordance with an embodiment of the present disclosure. FIG. 5 is a perspective view illustrating a memory device in accordance with an embodiment of the present disclosure.

Referring to FIGS. 4 and 5, a sectional view taken along line A1-A2 of the memory device, shown in FIG. 3. A peripheral structure PER may be stacked on a substrate SUB on which a contact open area OFC is defined. The peripheral circuit 170, shown in FIG. 1, may be included in the peripheral structure PER, and a portion of the peripheral circuit 170 is illustrated in FIG. 4. For example, a ground terminal GTN may be included in the substrate SUB of the contact opening region OFC, and a peripheral contact pCT may be located on the ground terminal GTN. The ground terminal GTN may be a junction formed by doping an impurity into the substrate SUB or may be a line made of a conductive material. When the ground terminal GTN is formed as the line, the ground terminal GTN may be formed by forming a trench in the substrate SUB and filling a conductive material in the trench. A peripheral line pMN may be located on the peripheral contact pCT. The peripheral line pMN may have a width that is wider than a width of the peripheral contact pCT in the Y direction. The peripheral contact pCT and the peripheral line pMN may be formed of a conductive material. A peripheral insulating layer pIS may be formed at the periphery of the peripheral line pMN and the peripheral contact pCT.

A source line SL located on the peripheral structure PER may include first to third source layers SL1 to SL3 and first and second buffer layer BF1 and BF2. The first and second buffer layers BF1 and BF2 may be located between the first to third source layers SL1 to SL3. For example, the first buffer layer BF1 may be located on the first source layer SL1, the third source layer SL3 may be located on the first buffer layer BF1, the second buffer layer BF2 may be located on the third source layer SL3, and the second source layer SL2 may be located on the second buffer layer BF2. The first to third source layers SL1 to SL3 may be formed of a conductive material. For example, the first to third source layers SL1 to SL3 may be formed of a conductive material, such as poly-silicon, tungsten, or nickel. The first and second buffer layers BF1 and BF2 may be formed of an insulating layer. For example, the first and second buffer layers BF1 and BF2 may be formed of an oxide layer. For example, the first and second buffer layers BF1 and BF2 may be formed of a silicon oxide layer.

The source line SL may be divided into a first portion PR1 and a second portion PR2 with respect to the contact open region OFC. On a section taken along the line A1-A2, the first and second portions PR1 and PR2 may be located at both ends of the contact open region OFC, which looks as if the source line SL is separated by the contact open region OFC. However, the source line SL extends continuously in other sectional views of the memory block. Therefore, the first and second portions PR1 and PR2 located at both the ends of the contact open region OFC are, in fact, continuous. For example, referring to FIGS. 3 and 4, although the source line SL might not be located below the region surrounded by the first support pattern 1SP, the source line SL may be located below (below in the Z direction) the second support patterns 2SP and the cell plugs CP.

A discharge contact DCC and first and second etch stop patterns ESP1 and ESP2 may be located in the contact open region OFC between the source lines SL, and the space between the discharge contact DCC and the first and second etch stop patterns ESP1 and ESP2 may be filled with an open region insulating layer OSI. The discharge contact DCC may be in contact with the peripheral line pMN while penetrating the open region insulating layer OSI through the center of the contact open region OFC. The discharge contact DCC may be formed of a conductive material.

The first and second etch stop patterns ESP1 and ESP2 may be located at both sides of the discharge contact DCC and may be spaced apart from the discharge contact DCC. Referring back to FIG. 3, each of the first and second etch stop patterns ESP1 and ESP2 may be formed in a line shape along the X direction and may be arranged to be parallel to each other. The first and second etch stop patterns ESP1 and ESP2 may be formed of a conductive layer. For example, the first and second etch stop patterns ESP1 and ESP2 may be formed of the same material as the second source layer SL2. For example, the first and second etch stop patterns ESP1 and ESP2 may be formed of a conductive material, such as poly-silicon, tungsten, or nickel. Each of the first and second etch stop patterns ESP1 and ESP2 may be maintained in a floating state. For example, each of the first and second etch stop patterns ESP1 and ESP2 might not be in contact with another conductive material. The first etch stop pattern ESP1 may be located between the first portion PR1 of the source line SL and the discharge contact DCC, and the second etch stop pattern ESP2 may be located between the second portion PR2 of the source line SL and the discharge contact DCC. The first and second etch stop patterns ESP1 and ESP2 may be symmetrical to each other with respect to the discharge contact DCC and may have the same size.

The first etch stop pattern ESP1, among the first and second etch stop patterns ESP1 and ESP2, will be described in detail as follows. The first etch stop pattern ESP1 may have a first width W1, a width meaning a length in the Y direction. The first etch stop pattern ESP1 may be located closer to the first portion PR1 of the source line SL than the discharge contact DCC. For example, when assuming that a width between the first etch stop pattern ESP1 and the first portion PR1 is a second width W2 and a width between the first etch stop pattern ESP1 and the discharge contact DCC is a third width W3, the third width W3 may be narrower than the second width W2. The third width W3 may be narrower than the first width W1. That is, the third width W3 may be narrower than the first width W1, and the second width W2 may be narrower than the third width W3. Referring to FIG. 4, the first width W1 may be a length between a left-side surface and a right-side surface of the first etch stop pattern ESP1, and the third width W3 may be a length between a right-side surface of the discharge contact DCC and the left-side surface of the first etch stop pattern ESP1. The second width W2 may be a length between the right-side surface of the first etch stop pattern ESP1 and a left-side surface of the first portion PR1 of the source line SL. The ratio of widths may result in a greater contact area between the first and second sub-support patterns 1sSP and 2sSP and the first and second etch stop patterns ESP1 and ESP2, which is greater than a contact area between the first and second sub-support patterns 1sSP and 2sSP and the first and second portions PR1 and PR2 of the source line SL.

A width obtained by adding up the first to third widths W1 to W3 may be a width between the discharge contact DCC and the source line SL. For example, the width between the discharge contact DCC and the source line SL may be a fourth width W4. The fourth width W4 may provide a sufficient margin to avoid a bridge from occurring between the source line SL and the discharge contact DCC due to the first and second etch stop patterns ESP1 and ESP2.

A stack structure STK may be located on the source line SL. The stack structure STK may include first material layers MT1 and gate lines GL, which are alternately stacked. The first material layers MT1 may be formed of an insulating material, and the gate lines GL may be formed of a conductive material. For example, the first material layers MT1 may be formed of an oxide layer, and the gate lines GL may be formed of a metal material, such as tungsten (W), molybdenum (Mo), cobalt (Co), or nickel (Ni), or a semiconductor material, such as silicon (Si) or poly-silicon (Poly-Si). However, the present disclosure is not limited thereto.

First and second material layers MT1 and MT2, which are alternately stacked, may be located on the open region insulating layer OSI, the discharge contact DCC, and the first and second etch stop patterns ESP1 and ESP2 of the contact open region OFC. The second material layers MT2 may be formed of a nitride layer.

First and second slit structures 1SLT and 2SLT penetrating the stack structure STK and a portion of the source line SL may be located on the source line SL. For example, the first slit structure 1SLT may be located on the first portion PR1 of the source line SL, and the second slit structure 2SLT may be located on the second portion PR2 of the source line SL. The first slit structure 1SLT may be located in a first slit region 1SR, and the second slit structure 2SLT may be located in a second slit region 2SR. The first and second slit structures 1SLT and 2SLT may be formed of an insulating layer or a conductive layer. When the first and second slit structures 1SLT and 2SLT are formed of an insulating layer, only the first and second slit structures 1SLT and 2SLT may be formed in the first and second slit regions 1SR and 2SR. When the first and second slit structures 1SLT and 2SLT are formed of a conductive layer, the first and second slit structures 1SLT and 2SLT and slit insulating layers SIS located on sidewalls of the first and second slit structures 1SLT and 2SLT may be formed in the first and second slit regions 1SR and 2SR. When the first and second slit structures 1SLT and 2SLT are formed of the conductive layer, the first and second slit structures 1SLT and 2SLT may be source contacts, and bottom surfaces of the first and second slit structures 1SLT and 2SLT may be in contact with the source line SL. When the first and second slit structures 1SLT and 2SLT are formed of the conductive layer, the first and second slit structures 1SLT and 2SLT may be formed of poly-silicon, tungsten, nickel, or the like. The slit insulating layers SIS may be formed of an oxide layer. For example, the slit insulating layers SIS may be formed of a silicon oxide layer.

The first and second sub-support patterns 1sSP and 2sSP may be located between the contact open region OFC and the stack structure STK. The first sub-support pattern 1sSP may be located between the stack structure STK located on the first portion PR1 of the source line SL and the contact open region OFC, and the second sub-support pattern 2sSP may be located between the stack structure STK located on the second portion PR2 of the source line SL and the contact open region OFC. Therefore, side surfaces of the first and second sub-support patterns 1sSP and 2sSP, which are located within the contact open region OFC, may be in contact with the first and second material layers MT1 and MT2, and side surfaces of the first and second sub-support patterns 1sSP and 2sSP, which are located outside of the contact open region OFC, may be in contact with the first material layers MT1 and the gate lines GL. The first and second sub-support patterns 1sSP and 2sSP may be structures supporting the stack structure STK to avoid warping or degradation and may be formed of an insulating layer. For example, the first and second sub-support patterns 1sSP and 2sSP may be formed of an oxide layer. For example, the first and second sub-support patterns 1sSP and 2sSP may be formed of a silicon oxide layer. Bottom surfaces of the first and second sub-support patterns 1sSP and 2sSP may be in contact with the source line, the open region insulating layer OSI, and the first and second etch stop patterns ESP1 and ESP2.

A contact CT may be located between the first and second sub-support patterns 1sSP and 2sSP. The contact CT may be spaced apart from the first and second sub-support patterns 1sSP and 2sSP. Side surfaces CT may be in contact with the first and second material layers MT1 and MT2, and the bottom of the contact CT may be in contact with the discharge contact DCC. The contact CT may be formed of a conductive layer. For example, the contact CT may be formed of a conductive layer, such as poly-silicon, tungsten, or nickel.

Among the above-described structures, the first and second etch stop patterns ESP1 and ESP2 may be used to stop an etching process when a depth of trenches in which the first and second sub-support patterns 1sSP and 2sSP are located becomes a target depth. The etching process for forming the trenches is to be stopped when the depth of the trenches becomes the target depth. To this end, the etching process for forming the trenches may be stopped when a component different from a component of the stack structure STK is detected. For example, the etching process may be stopped when a component of the source line SL is detected.

When the first and second etch stop patterns ESP1 and ESP2 do not exist, the component of the source line SL may be detected late in the etching process when the area of the source line SL exposed through the trenches is excessively narrow. That is, when a width between the source line SL and the discharge contact DCC is excessively wide, an over-etching process may be performed, resulting in the source line SL and the discharge contact DCC being exposed. Therefore, a bridge may occur between the source line SL and the discharge contact DCC in a subsequent process of forming the third source layer SL3. In order to prevent the occurrence of the bridge, positive ions that are to be discharged through the source line SL and the discharge contact DCC may be moved to the source line SL when the width between the source line SL and the discharge contact DCC is formed excessively narrow. Accordingly, it is important to adjust the width between the source line SL and the discharge contact DCC.

In this embodiment, the first and second etch stop patterns ESP1 and ESP2 may be formed between the source line SL and the discharge contact DCC such that the width between the source line SL and the discharge contact DCC can be maintained as the fourth width W4. Due to the first and second etch stop patterns ESP1 and ESP2, the trenches filled with the first and second sub-support patterns 1sSP and 2sSP can be formed to the target depth, and a distance between the source line SL and the discharge contact DCC can be sufficiently secured.

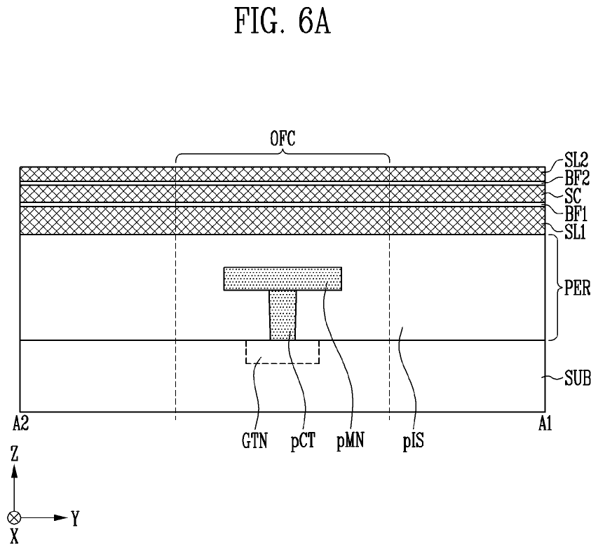

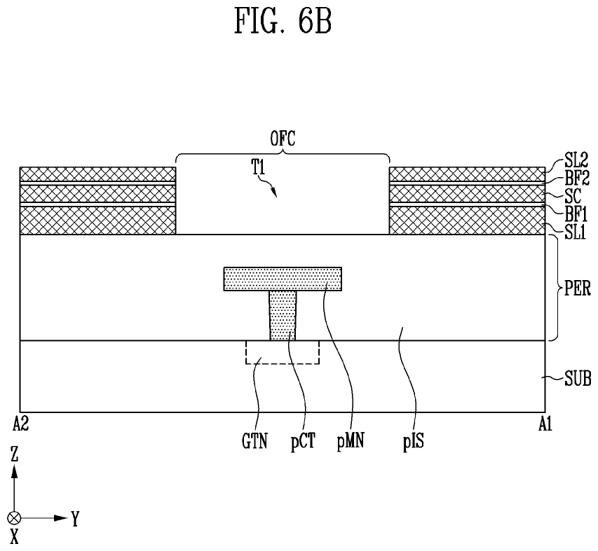

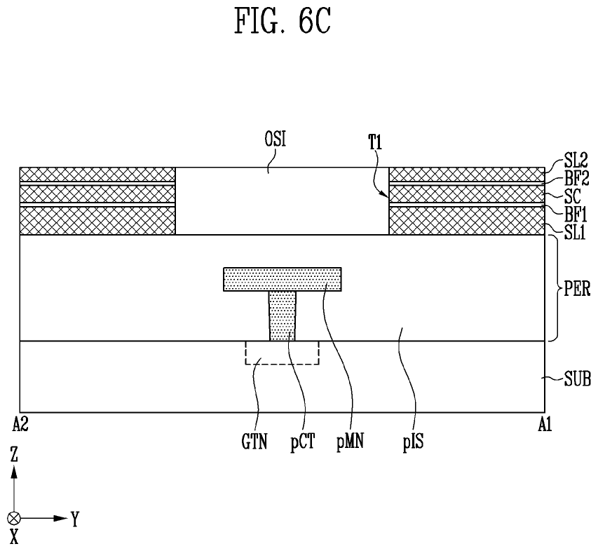

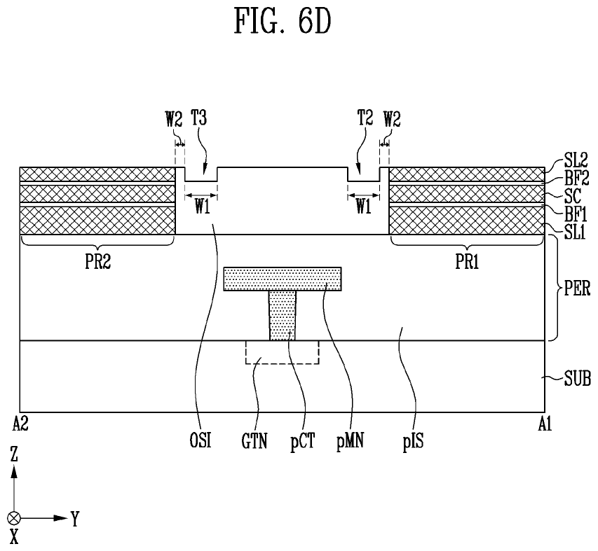

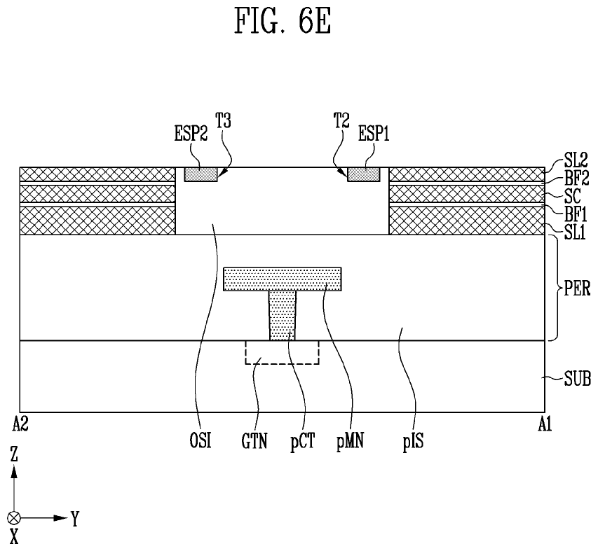

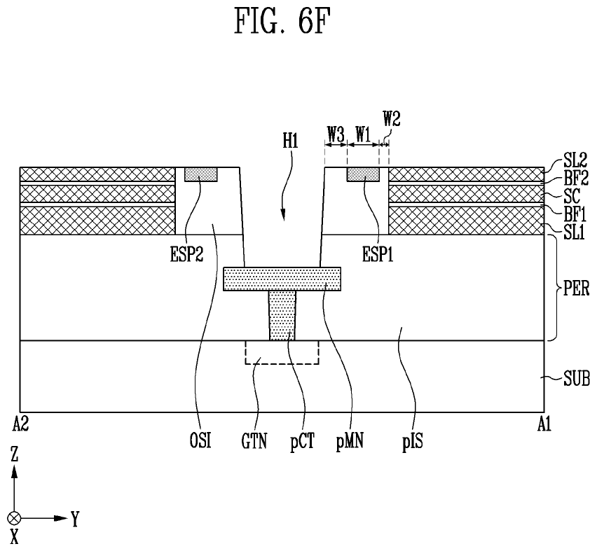

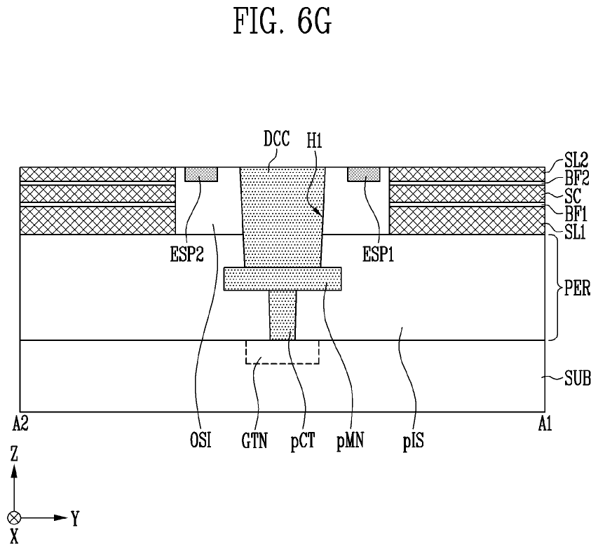

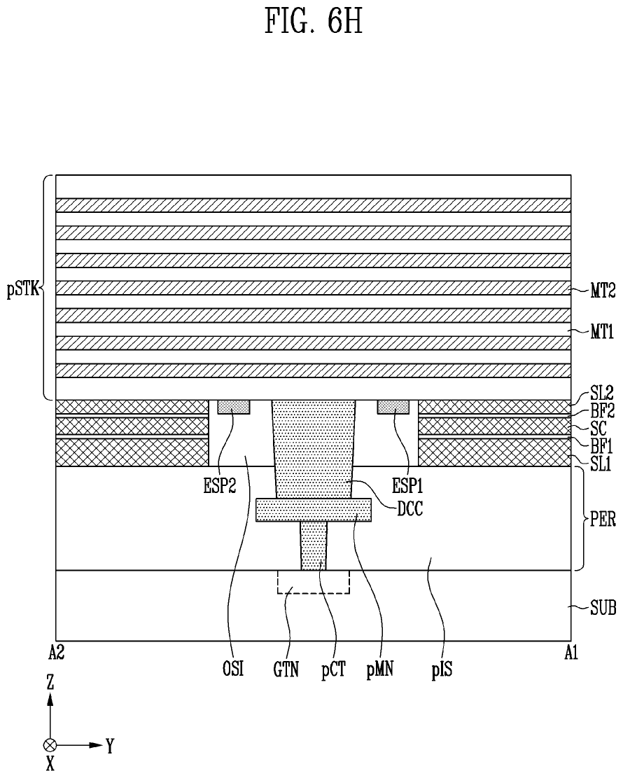

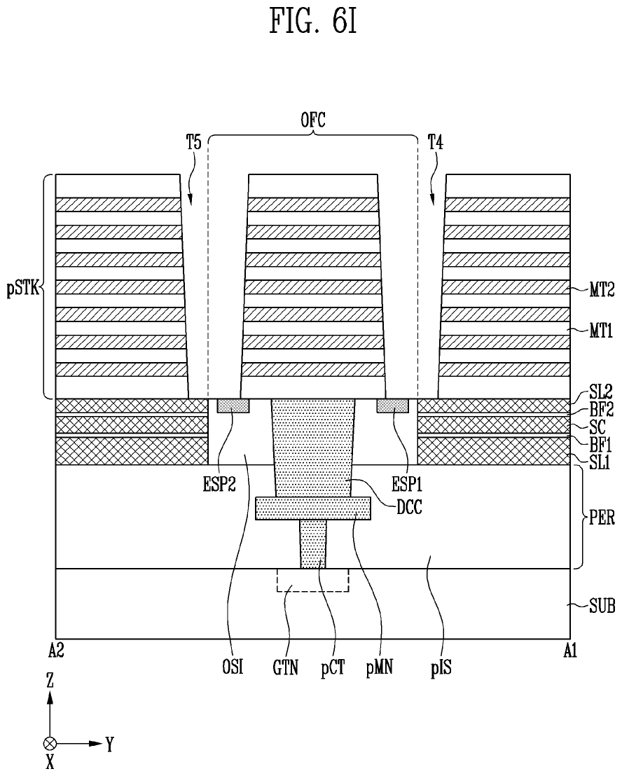

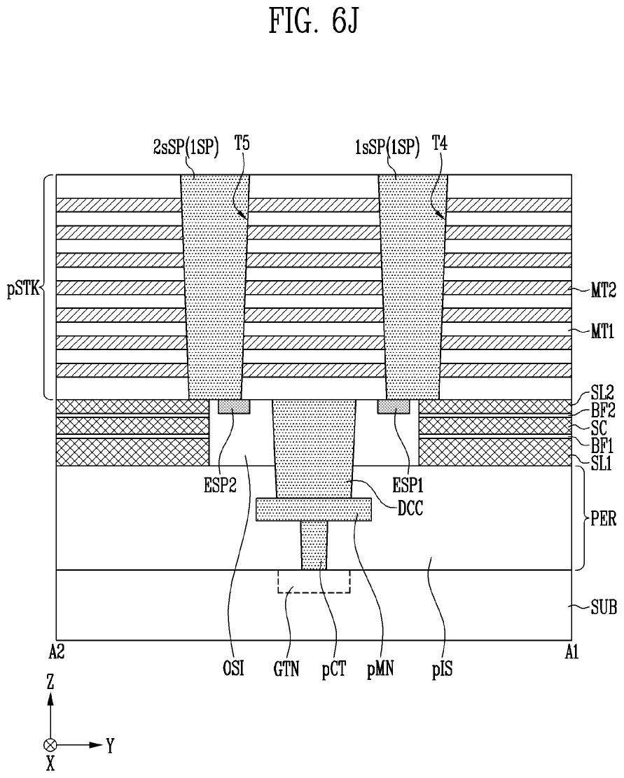

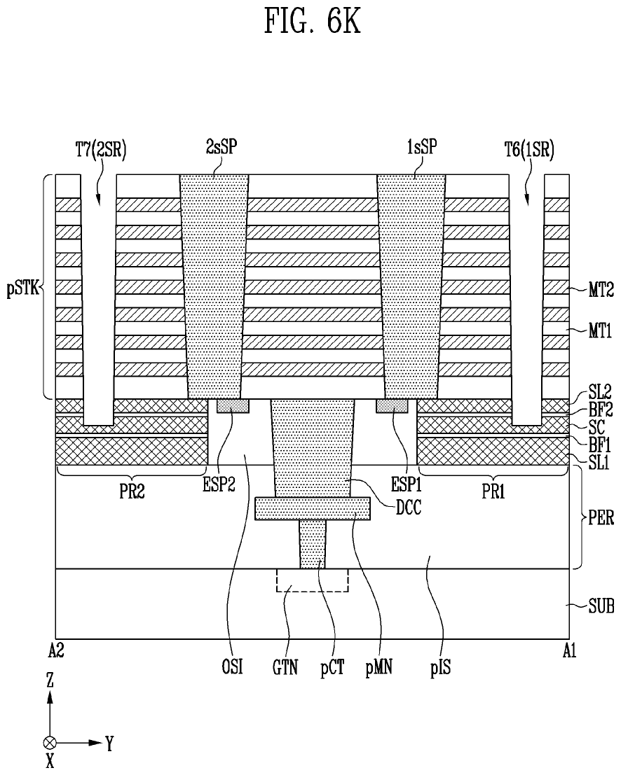

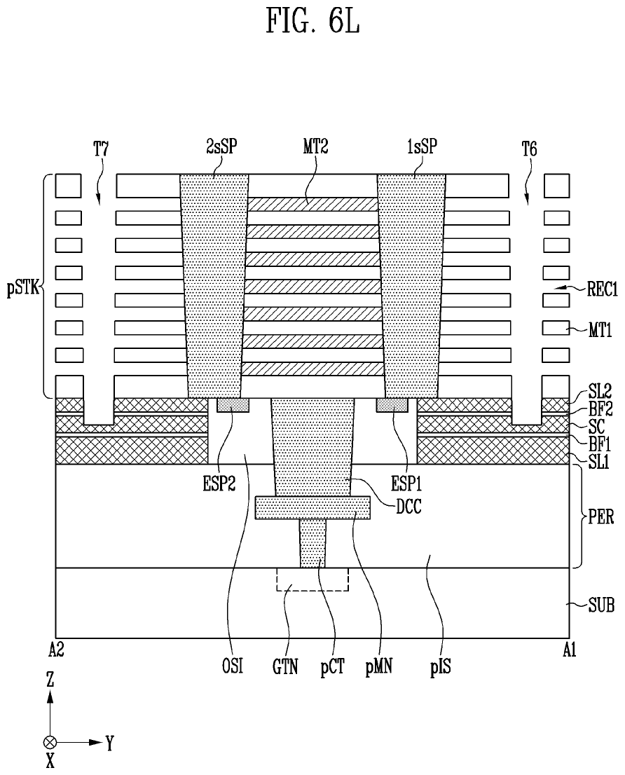

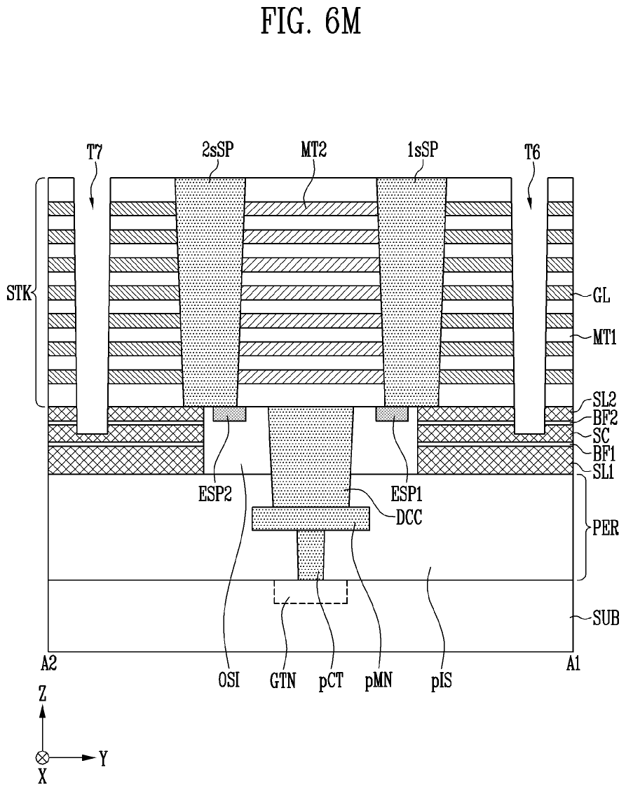

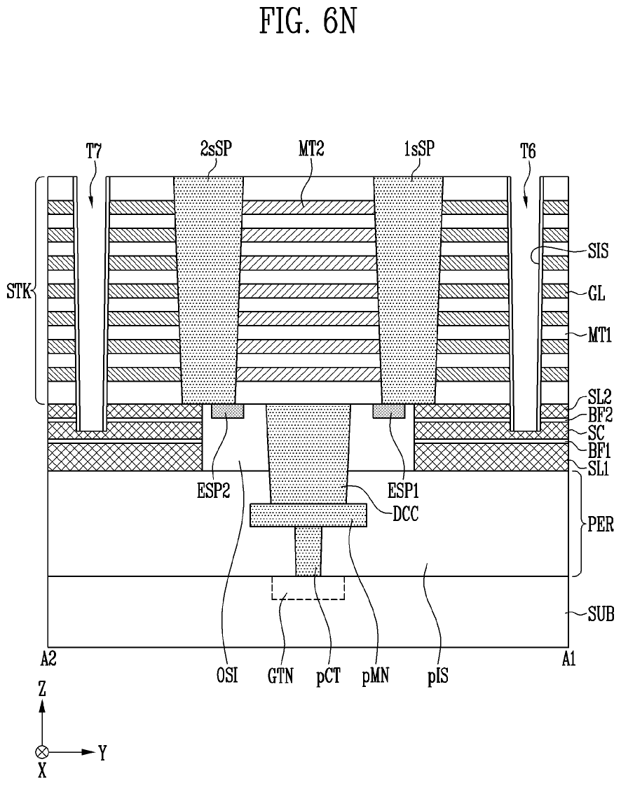

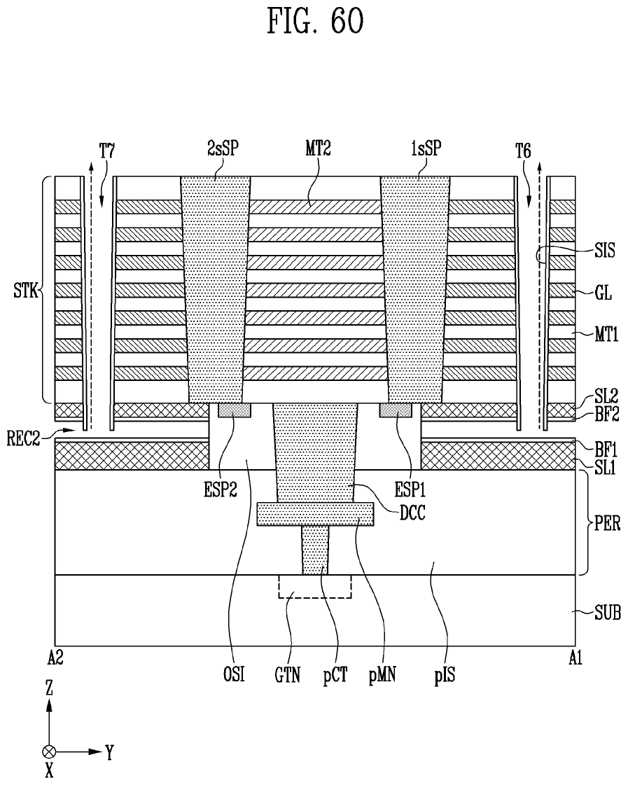

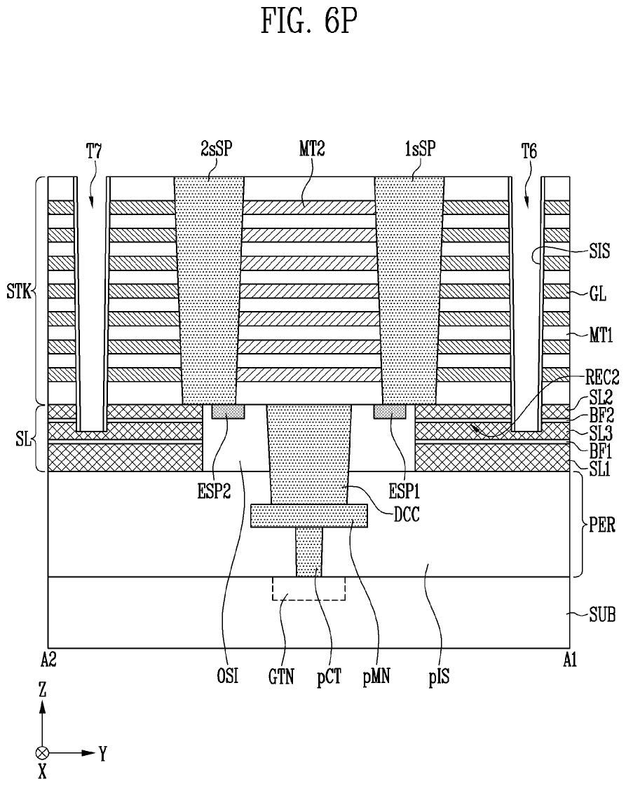

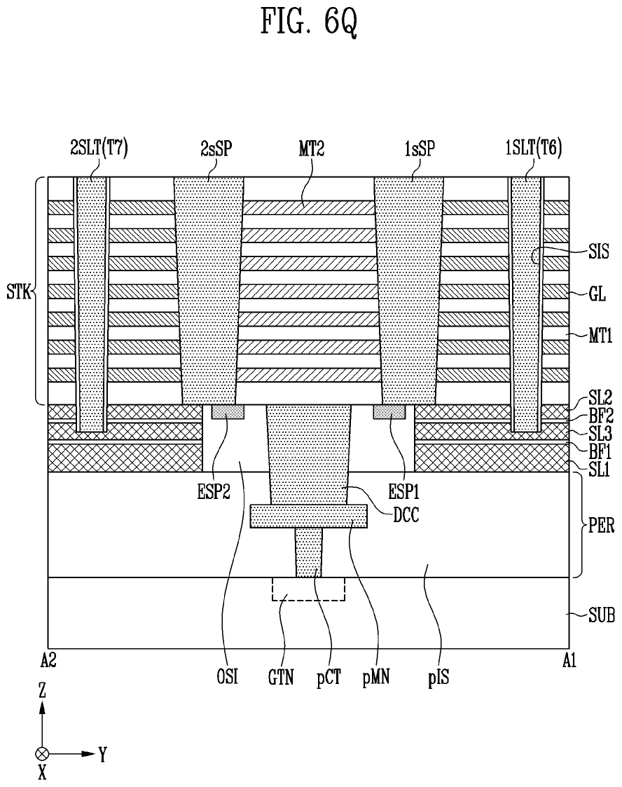

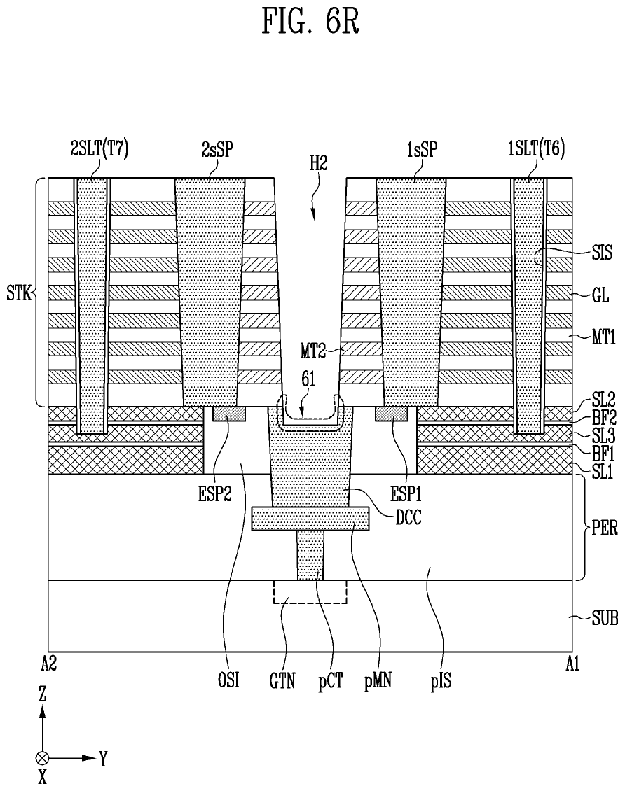

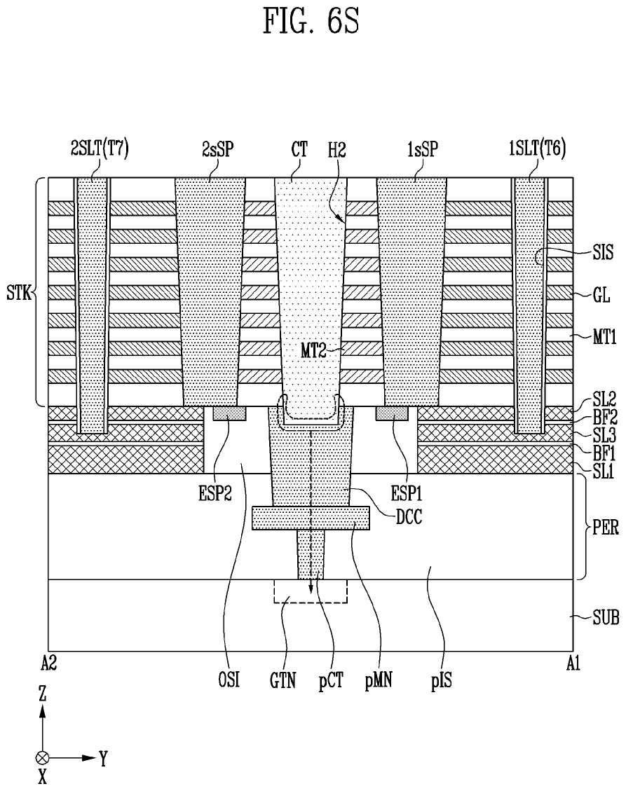

FIGS. 6A to 6S are views illustrating a manufacturing method of a memory device in accordance with an embodiment of the present disclosure.

Referring to FIG. 6A, a ground terminal GTN may be formed in a substrate SUB on which a contact open region OFC is defined. The contact open region OFC may be a region in which structures for electrically connecting a cell region and a peripheral structure PER to each other are to be located. The ground terminal GTN may be formed by doping an impurity into the substrate SUB or by forming a trench in the substrate SUB and filling the trench with a conductive material. The ground terminal GTN may be connected to a terminal to which a ground voltage is supplied.

The peripheral structure PER may be formed on the substrate SUB. The peripheral structure PER may include a peripheral contact pCT, a peripheral line pMN, and a peripheral insulating layer pIS. The peripheral contact pCT may be located on the ground terminal GTN, and the peripheral line pMN may be located on the peripheral contact pCT. The peripheral contact pCT may have a width that is narrower than a width of the ground terminal GTN. The peripheral line pMN may have a width that is wider than the width of the peripheral contact pCT. The peripheral contact pCT and the peripheral line pMN may be formed of a conductive material. The peripheral insulating layer pIS may be formed of an oxide layer surrounding the peripheral contact pCT and the peripheral line pMN. Although not shown in the drawing, structures included in the peripheral circuit (170 shown in FIG. 1) may be further included in the peripheral structure PER.

A first source layer SL1, a first buffer layer BF1, a sacrificial layer SC, a second buffer layer BF2, and a second source layer SL2 may be sequentially stacked on the peripheral structure PER. The first and second source layers SL1 and SL2 may be formed of a conductive layer, and the first and second buffer layers BF1 and BF2 may be formed of an insulating layer. For example, the first and second source layers SL1 and SL2 may be formed of a conductive layer, such as poly-silicon, tungsten, or nickel, and the first and second buffer layers BF1 and BF2 may be formed of an oxide layer, such as a silicon oxide layer. The sacrificial layer SC may be formed of the same material as the first and second source layers SL1 and SL2 or may be formed of a material having an etch selectivity that is different from an etch selectivity of the first and second buffer layers BF1 and BF2. For example, the sacrificial layer SC may be formed of a material having an etch selectivity that is higher than an etch selectivity of the first and second buffer layers BF1 and BF2 in a wet etching process. The sacrificial layer SC may be thinner than the first source layer SL1, and the second source layer SL2 may be thinner than the sacrificial layer SC. The first and second buffer layers BF1 and BF2 may have the same thickness and may be thinner than the second source layer SL2.

Referring to FIG. 6B, the second source layer SL2, the second buffer layer BF2, the sacrificial layer SC, the first buffer layer BF1, and the first source layer SL1, which are formed in the contact open region OFC, may be removed, thereby forming a first trench T1 exposing a portion of the peripheral structure PER. For example, the first trench T1 may be formed by performing a dry etching process. The etching process for forming the first trench T1 may be performed until a portion of the peripheral insulating layer pIS included in the peripheral structure PER is exposed.

Referring to FIG. 6C, an open region insulating layer OSI may be filled in the first trench T1. The open region insulating layer OSI may be formed of an oxide layer. For example, the open region insulating layer OSI may be formed of a silicon oxide layer. After the open region insulating layer OSI is formed on the entire structure including the first trench T1, the open region insulating layer OSI may remain in only the first trench through a planarization process until the second source layer SL2 is exposed.

Referring to FIG. 6D, second and third trenches T2 and T2 may be formed in regions in which first and second etch stop patterns (ESP1 and ESP2, which are shown in FIG. 4) are to be formed in the open region insulating layer OSI. A depth of the second and third trenches T2 and T3 may be equal to or less than the thickness of the second source layer SL2. For example, the second trench T2 may be formed in a region that is close to a first portion PR1, and the third trench T3 may be formed in a region that is close to a second portion PR2. Each of the second and third trenches T2 and T3 may have a first width W1. A width between the second trench T2 and the first portion PR1 may be a second width W2, and a width between the third trench T3 and the second portion PR2 may also be the second width W2. The second width W2 may be narrower than the first width W1.

Referring to FIG. 6E, first and second etch stop patterns ESP1 and ESP2 may be formed in the second and third trenches T2 and T3. For example, the first etch stop pattern ESP1 may be formed in the second trench T2, and the second etch stop pattern ESP2 may be formed in the third trench T3. For example, the first and second etch stop patterns ESP1 and ESP2 may be formed of a conductive layer. For example, the first and second etch stop patterns ESP1 and ESP2 may be formed of the same material as the second source layer SL2. For example, the first and second etch stop patterns ESP1 and ESP2 may be formed of a conductive material, such as poly-silicon, tungsten, or nickel. After a conductive layer corresponding to the first and second etch stop patterns ESP1 and ESP2 is formed on the entire structure, a planarization process may be performed until the open region insulating layer OSI is exposed such that the first and second etch stop patterns ESP1 and ESP2 remain in only the second and third trenches T2 and T3.

Referring to FIG. 6F, the open region insulating layer OSI between the first and second etch stop patterns ESP1 and ESP2 and a portion of the peripheral insulating layer pIS may be removed, thereby forming a first hole H1 exposing a portion of the peripheral line pMN. The first hole H1 may penetrate the open region insulating layer OSI and may penetrate a portion of the peripheral insulating layer pIS, thereby exposing a portion of the peripheral line pMN. A dry etching process may be performed to form the first hole H1. A width between the first hole H1 and the first or second etch stop pattern ESP1 or ESP2 may be a third width W3. The third width W3 may be wider than the second width W2 and may be narrower than the first width W1.

Referring to FIG. 6G, a discharge contact DCC may be formed in the first hole H1. The discharge contact DCC may be formed of a conductive layer. For example, the discharge contact DCC may be formed of a conductive material, such as poly-silicon, tungsten, or nickel. Since the discharge contact DCC is formed in a state in which the peripheral line pMN is exposed through a bottom surface of the first hole H1, the discharge contact DCC may be in contact with the peripheral line pMN.

Referring to FIG. 6H, a pre-stack structure pSTK may be formed on the top of the second source layer SL2, the open region insulating layer OSI, the first and second etch stop patterns ESP1 and ESP2, and the discharge contact DCC. The pre-stack structure pSTK may be formed by alternately stacking first and second material layers MT1 and MT2. For example, a first material layer MT1 may be formed on the top of the second source layer SL2, the open region insulating layer OSI, the first and second etch stop patterns ESP1 and ESP2, and the discharge contact DCC, and a second material layer MT2 may be formed on the first material layer MT1. A first material layer MT1 may be again formed on the top of the second material layer MT2, and so on. In this manner, the pre-stack structure pSTK including the first and second material layers MT1 and MT2, which are alternately stacked, may be formed. The first material layers MT1 may be formed of an oxide layer, and the second material layers MT2 may be formed of a material having an etch selectivity that is different from an etch selectivity of the first material layers MT1. For example, the second material layers MT2 may be formed of a nitride layer.

Referring to FIG. 6I, a portion of the pre-stack structure pSTK may be etched, thereby forming fourth and fifth trenches T4 and T5 exposing portions of the second source layer SL2, the open region insulating layer OSI, and the first and second etch stop patterns ESP1 and ESP2. The fourth and fifth trenches T4 and T5 may be partially formed in a boundary region of the contact open region OFC. Therefore, the first and second material layers MT1 and MT2 included in the pre-stack structure pSTK may be isolated into portions included in the contact opening region OFC and portion included in outside of the contact open region OFC. An etching process for forming the fourth and fifth trenches T4 and T5 may be performed as an anisotropic dry etching process. The etching process for forming the fourth and fifth trenches T4 and T5 may be performed until the second source layer SL2, the first etch stop pattern ESP1, or the second etch stop pattern ESP2 is exposed. For example, the etching process for forming the fourth and fifth trenches T4 and T5 may be stopped when a component of the second source layer SL2, the first etch stop pattern ESP1, or the second etch stop pattern ESP2 is detected. The fourth trench T4 may be formed to expose portions of the first etch stop pattern ESP1 and the second source layer SL2, and the fifth trench T5 may be formed to expose portions of the second etch stop pattern EPS and the second source layer SL2. In the etching process for forming the fourth and fifth transistors T4 and T5, since an area of the second source layer SL2 exposed through the fourth and fifth trenches T4 and T5 is narrow, an area with which the first and second etch stop patterns ESP1 and ESP2 are exposed is wider than the area with which the second source layer SL2 is exposed even when any component of the second source layer SL2 is not detected. Therefore, a component of the first or second etch stop pattern ESP1 or ESP2 may be detected. When the component of the first or second etch stop pattern ESP1 or ESP2 is detected, the etching process may be stopped, and thus, over-etching of the etching process for forming the fourth and fifth trenches T4 and T5 can be prevented.

Referring to FIG. 6J, first and second sub-support patterns 1sSP and 2sSP may be formed in the fourth and fifth trenches T4 and T5. The first sub-support pattern 1sSP may be formed in the fourth trench T4, and the second sub-support pattern 2sSP may be formed in the fifth trench T5. The first and second sub-support patterns 1sSP and 2sSP may be formed of an insulating layer. For example, the first and second sub-support patterns 1sSP and 2sSP may be formed of an oxide layer. For example, the first and second sub-support patterns 1sSP and 2sSP may be formed of a silicon oxide layer.

Referring to FIG. 6K, sixth and seventh trenches T6 and T7 may be formed in first and second slit regions 1SR and 2SR of the pre-stack structure pSTK. The first and second slit regions 1SR and 2SR may be regions dividing memory blocks. Therefore, the sixth and seventh trenches T6 and T7 may be formed to expose a portion of the sacrificial layer SC while penetrating the pre-stack structure pSTK, the second source layer SL2, and the second buffer layer BF2. The sixth trench T6 may be formed in the first slit region 1SR, and the seventh trench T7 may be formed in the second slit region 2SR. Since the sixth and seventh trenches T6 and T7 penetrate the pre-stack structure pSTK, the first and second material layers MT1 and MT2 may be exposed through sidewalls of the sixth and seventh trenches T6 and T7.

Referring to FIG. 6L, the second material layers MT2 exposed through the sixth and seventh trenches T6 and T7 may be removed. For example, an isotropic dry etching process or a wet etching process may be performed to remove the second material layers MT2. Since the second material layers MT2 between the first and second sub-support patterns 1sSP and 2sSP are not exposed by the first and second sub-support patterns 1sSP and 2sSP, the second material layers MT2 may remain between the first and second sub-support patterns 1sSP and 2sSP. As the second material layers MT2 are removed, first recesses REC1 may be formed between the first material layers MT1. The first recesses REC1 may mean empty spaces between the first material layers MT1.

Referring to FIG. 6M, gate lines GL may be formed by filling a conductive layer in the first recesses (REC1 shown in FIG. 6L) between the first material layers MT1. The gate lines GL may be formed of a metal material, such as tungsten (W), molybdenum (Mo), cobalt (Co), or nickel (Ni), or a semiconductor material, such as silicon (Si) or poly-silicon (Poly-Si).

Referring to FIG. 6N, sidewall insulating layers SIS may be formed on the sidewalls of the sixth and seventh trenches T6 and T7. The sidewall insulating layers SIS may be formed of an oxide layer. For example, the sidewall insulating layers SIS may be formed of a silicon oxide layer. The sidewall insulating layers SIS may be formed using the following method. For example, after an oxide layer corresponding to the sidewall insulating layers SIS is formed along a surface of the entire structure including the sixth and seventh trenches T6 and T7, the oxide layer that is formed on bottom surfaces of the sixth and seventh trenches T6 and T7 and is formed on a top surface of the pre-stack structure pSTK may be removed. The oxide layer remaining on the sidewalls of the sixth and seventh trenches T6 and T7 may become the sidewall insulating layers SIS. A portion of the sacrificial layer SC may be exposed through the bottom surfaces of the sixth and seventh trenches T6 and T7 in which the sidewall insulating layers SIS are formed.

Referring to FIG. 6O, an etching process for removing the sacrificial layer SC exposed through the sixth and seventh trenches T6 and T7 may be performed. For example, a wet etching process may be performed as the etching process for removing the sacrificial layer SC. The wet etching process may be performed using an etchant having an etch selectivity with respect to the sacrificial layer SC, which is higher than an etch selectivity with respect to the sidewall insulating layers SIS, the first buffer layer BF1, and the second buffer layer BF2. Therefore, the sacrificial layer SC located between the first and second buffer layers BF1 and BF2 may be removed through the sixth and seventh trenches T6 and T7. As the sacrificial layer SC is removed, a second recess REC2 may be formed between the first and second buffer layers BF1 and BF2.

Referring to FIG. 6P, a third source layer SL3 may be filled in the second recess REC2. The third source layer SL3 may be formed of the same material as the first and second source layers SL1 and SL2. For example, the third source layer SL3 may be formed of a conductive material, such as poly-silicon, tungsten, or nickel. As the third source layer SL3 is formed, a source line SL may be formed, which includes the first to third source layers SL1 to SL3 and the first and second buffer layers BF1 and BF2. Alternatively, after the first and second buffer layers BF1 and BF2 are removed, the third source layer SL3 may be formed. In this embodiment, the first and second buffer layers BF1 and BF2 may be maintained. However, in some embodiments, the first and second buffer layers BF1 and BF2 may be removed. The third source layer SL3 may be formed through the sixth and seventh trenches. After the third source layer SL3 is filled in the second recess REC2, the third source layer SL3 may be formed along lower portions of the sidewalls of the sixth and seventh trenches T6 and T7, and therefore, an etching process or cleaning process for removing a portion of the third source layer SL3 remaining in the sixth and seventh trenches T6 and T7 may be further performed.

Referring to FIGS. 6Q, first and second slit structures 1SLT and 2SLT may be formed in the sixth and seventh trenches T6 and T7. The first slit structure 1SLT may be formed in the sixth trench T6, and the second slit structure 2SLT may be formed in the seventh trench T7. The first and second slit structures 1SLT and 2SLT may be formed of an insulating material or a conductive material. When the first and second slit structures 1SLT and 2SLT are formed of the conductive material, each of the first and second slit structures 1SLT and 2SLT may become a source contact in contact with the source line SL. The source contact may be a contact transferring a source voltage to the source line SL.

Referring to FIG. 6R, portions of the first and second material layers MT1 and MT2 between the first and second sub-support patterns 1sSP and 2sSP may be removed, thereby forming a second hole H2 exposing a portion of the discharge contact DCC. An etching process for forming the second hole H2 may be performed as an anisotropic dry etching process. The anisotropic dry etching process may be mainly performed using a Reactive Ion Etching (RIE) method or a method obtained by applying the RIE method. Plasma may be used in the etching process using the RIE method or the method obtained by applying the RIE method. Positive ions generated by the plasma may collide with an etching target layer, and therefore, the binding force of a surface of the etching target layer may become weak. Molecules at a portion at which the binding force becomes weak in the etching target layer may be discharged, together with radicals, from a chamber. As the depth of the second hole H2 becomes deeper, some positive ions may remain on a lower portion 61 of the second hole H2.

Referring to FIG. 6S, a contact CT may be formed in the second hole H2. The contact CT may be formed of a conductive layer. After the contact CT is formed, the positive ions remaining in the second hole H2 may be discharged from the memory device through the discharge contact DCC and the ground terminal GTN.

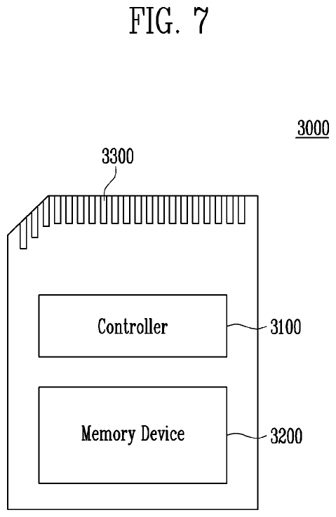

FIG. 7 is a diagram illustrating a memory card system to which the memory device of the present disclosure is applied.

Referring to FIG. 7, the memory card system 3000 may include a controller 3100, a memory device 3200, and a connector 3300.

The controller 3100 may be connected to the memory device 3200. The controller 3100 may access the memory device 3200. For example, the controller 3100 may control a program, read, or erase operation or may control a background operation of the memory device 3200. The controller 3100 may provide an interface between the memory device 3200 and a host. The controller 3100 may drive firmware for controlling the memory device 3200. For example, the controller 3100 may include components, such as a Random Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. Exemplarily, the controller 3100 may communicate with the external device through at least one of various communication protocols, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells and may be configured identically to the memory device 100, shown in FIG. 1.

The controller 3100 and the memory device 3200 may be integrated into a single semiconductor device to constitute a memory card. For example, the controller 3100 and the memory device 3200 may constitute a memory card, such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

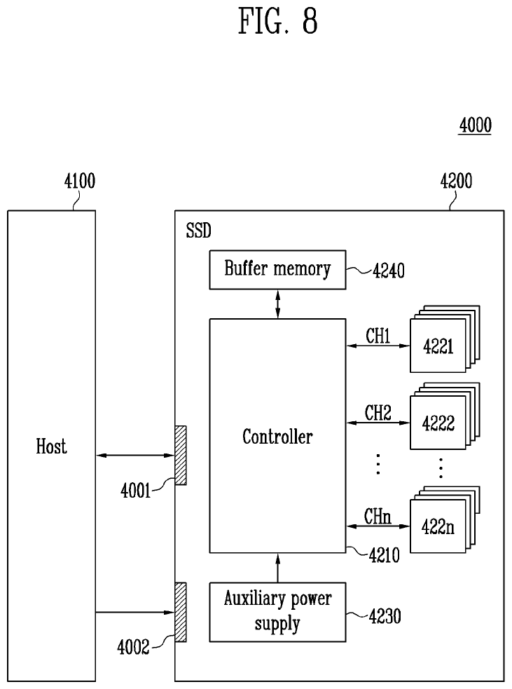

FIG. 8 is a diagram illustrating a Solid State Drive (SSD) system to which the memory device of the present disclosure is applied.

Referring to FIG. 8, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be a signal defined by at least one of interfaces, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100, shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power input from the host 4100 and charge the power PWR. When the supply of power from the host 4100 is not smooth, the auxiliary power supply 4230 may provide power of the SSD 4200. Exemplarily, the auxiliary power supply 4230 may be located in the SSD 4200 or may be located outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n or may temporarily store meta data (e.g., a mapping table) of the memory devices 4221 to 422n. The buffer memory 4240 may include volatile memories, such as a DRAM, an SDRAM, a DDR SDRAM, an LPDDR SDRAM, and a GRAM or nonvolatile memories such as a FRAM, a ReRAM, an STT-MRAM, and a PRAM.

In accordance with the present disclosure, as a margin between a source line and a discharge contact is secured, occurrence of a bridge between the source line and the discharge contact can be prevented, and an increase in size of the memory device can be prevented.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made based on the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made based on the technological scope of the present disclosure in addition to the embodiments disclosed herein.

What is claimed is:

1. A memory device comprising:
a discharge contact;
a source line adjacent to and spaced apart from the discharge contact;
an etch stop pattern located between the discharge contact and the source line, the etch stop pattern being closer to the source line than the discharge contact; and
a sub-support pattern located on the source line and the etch stop pattern.

2. The memory device of claim 1, wherein a width of the etch stop pattern is a first width,
wherein a width between the etch stop pattern and the source line is a second width, and
wherein the second width is less than the first width.

3. The memory device of claim 2, wherein a width between the etch stop pattern and the discharge contact is a third width, and
wherein the third width is greater than the second width.

4. The memory device of claim 1, wherein the etch stop pattern is formed of the same material as the source line.

5. The memory device of claim 1, wherein the etch stop pattern is formed of a conductive material.

6. The memory device of claim 1, wherein the etch stop pattern is formed of poly-silicon, tungsten, or nickel.

7. The memory device of claim 1, wherein the discharge contact is formed of a conductive layer.

8. The memory device of claim 1, further comprising:
a contact located on the top of the discharge contact; and
a peripheral line, a peripheral contact, and a ground terminal, located below the discharge contact.

9. The memory device of claim 1, further comprising a slit structure located on the source line, the slit structure being spaced apart from the sub-support pattern.

10. The memory device of claim 9, wherein the slit structure is formed of an insulating material or a conductive material.

11. The memory device of claim 1, further comprising an open region insulating layer filling a space between the source line and the discharge contact.

12. The memory device of claim 11, wherein the etch stop pattern is located in the open region insulating layer.

13. The memory device of claim 1, wherein a contact area between the sub-support pattern and the etch stop pattern is greater than a contact area between the sub-support pattern and the source line.

14. A memory device comprising:
a first portion and a second portion of a source line, extending in a first direction, the first portion and the second portion being arranged to be parallel to each other;
a discharge contact located between the first portion and the second portion of the source line;
a first etch stop pattern located between the discharge contact and the first portion of the source line;
a second etch stop pattern located between the discharge contact and the second portion of the source line;
a first sub-support pattern located on a region in which the first portion of the source line is adjacent to and spaced apart from the first etch stop pattern; and
a second sub-support pattern located on a region in which the second portion of the source line is adjacent to and spaced apart from the second etch stop pattern.

15. The memory device of claim 14, wherein the first and second etch stop patterns extend in the first direction and are arranged to be parallel to each other.

16. The memory device of claim 14, wherein each of the first and second etch stop patterns is floated.

17. The memory device of claim 14, wherein a width between the first or second etch stop pattern and the discharge contact is greater than a width between the first or second etch stop pattern and the respective first or second portion of the source line.

18. The memory device of claim 14, wherein the first sub-support pattern is in contact with a portion of the first etch stop pattern and a portion of the first portion of the source line, and
wherein the second sub-support pattern is in contact with a portion of the second etch stop pattern and a portion of the second portion of the source line.

19. The memory device of claim 18, wherein a contact area between the first and second etch stop patterns and the respective first and second sub-support patterns is greater than a contact area between the first and second portions of the source line and the respective first and second sub-support patterns.

20. The memory device of claim 14, wherein the first and second etch stop patterns are formed of the same material as the source line in contact with the first and second sub-support patterns.

21. The memory device of claim 14, wherein the first and second etch stop patterns are formed of poly-silicon, tungsten, or nickel.

22. A method of manufacturing a memory device, the method comprising:
forming a first portion and a second portion, which correspond to a source line, on a peripheral structure, and forming an open region insulating layer between the first and second portions;
forming, in the open region insulating layer, a first etch stop pattern adjacent to the first portion and a second etch stop pattern adjacent to the second portion;
forming a discharge contact penetrating the open region insulating layer between the first and second etch stop patterns;
forming a pre-stack structure on the first and second portions, the first and second etch stop patterns, the open region insulating layer, and the discharge contact;
performing an etching process for forming a first trench exposing a portion of the first etch stop pattern and a portion of the first portion while penetrating the pre-stack structure and a second trench exposing a portion of the second etch stop pattern and a portion of the second portion while penetrating the pre-stack structure; and
forming a first sub-support pattern in the first trench and forming a second sub-support pattern in the second trench.

23. The method of claim 22, wherein the forming of the first and second portions on the peripheral structure and the open region insulating layer between the first and second portions includes:
forming a structure corresponding to the source line on the peripheral structure;
allowing the first and second portions to remain by removing a portion of the structure; and
forming the open region insulating layer between the first and second portions.

24. The method of claim 23, wherein the forming of the structure includes sequentially stacking, on the peripheral structure, a first source layer, a first buffer layer, a sacrificial layer, a second buffer layer, and a second source layer.

25. The method of claim 22, wherein the first and second etch stop patterns are formed of the same material as a layer located at an uppermost end among layers included in the first and second portions.

26. The method of claim 24, wherein the etching process is stopped when the first portion, the second portion, the first etch stop pattern, or the second etch stop pattern is exposed.
